(19) United States
(12) Patent Application Publication
(10) Pub. No.: US 2025/0279334 A1
(43) Pub. Date: Sep. 4, 2025

(54) Novel 3D IC heat dissipation apparatus and method

(71) Applicant: Banqiu Wu, Katy, TX (US)

(72) Inventor: Banqiu Wu, Katy, TX (US)

(21) Appl. No.: 19/098,983

(22) Filed: May 19, 2025

(51) Int. Cl. H01L 23/38; H10N 10/17

(52) U.S. Cl. CPC H01L 23/38; H10N 10/17

(57) ABSTRACT

A self-cooled interposer for three-dimensional integrated circuit (3D IC) fabrication is disclosed. The interposer includes a thermoelectric cooler with through-cold-region vias (TCVs) that enable electrical interconnections between stacked components. A 3D chip stack comprising a graphics processing unit (GPU) and/or central processing unit (CPU), the thermoelectric-cooled interposer, and a high bandwidth memory (HBM) chip is formed, with interconnects routed through the cooled region. The self-cooled interposer effectively dissipates heat generated within the 3D IC stack, thereby significantly enhancing overall chip performance.

### FIELD

The present disclosure generally relates to three-dimensional (3D) stacked integrated circuit (IC) computer systems. More particularly, it pertains to a thermoelectric-cooled interposer for use in 3D IC computer systems.

### BACKGROUND

In recent years, artificial intelligence (AI) technologies have emerged as some of the most competitive and transformative innovations globally. AI is expected to see widespread adoption in applications such as autonomous driving, facial recognition, expert systems, medical diagnostics, and military technology. Economically, the AI market is projected to reach a scale of up to one trillion dollars annually, driving demand for increasingly powerful AI systems.

Modern AI systems are characterized by machine learning capabilities that distinguish them from traditional modeling systems. The feasibility of AI applications largely depends on computational speed, data transfer rates, and data volume, all of which are heavily influenced by microchip performance. Advances in semiconductor manufacturing have significantly enhanced the capabilities of graphics processing units (GPUs), which now play a central role in AI systems.

The core of AI functionality-its ability to learn and train-relies on access to vast datasets, necessitating integration with large-scale data centers. As AI expands into virtually every aspect of society and industry, the demand for comprehensive AI ecosystems is set to grow significantly.

Current AI computing systems typically include GPUs, high bandwidth memory (HBM), dynamic random-access memory (DRAM), and solid-state drives (SSDs). Among these, the data transfer rate between the GPU and HBM has become the most critical factor affecting system performance.

AI system performance is strongly tied to computational capability, which in turn depends on key system metrics such as transistor gate delay, interconnect delay, and internal/external memory data transfer rates.

To address gate delay and increase memory capacity, IC feature sizes have been progressively reduced through advances in lithographic technologies. Since the 1980s, projection lithography has employed increasingly shorter wavelengths—from 436 nm (g-line) to the current 13.5 nm extreme ultraviolet (EUV)—to achieve higher IC resolution.

However, since the early 2000s, interconnect delay has become a more pressing issue than gate delay, and internal memory speed limitations—often referred to as the “memory wall”—have hindered performance. While multi-core designs in GPUs and CPUs have been adopted as a workaround, these approaches are nearing their practical limits.

To overcome these constraints, attention has shifted to 3D IC stacking, which offers the potential to significantly reduce interconnect delays and alleviate the memory wall by providing more interconnects and shorter signal paths.

HBM technology, which leverages 3D IC stacking, has already been adopted in high-end AI computing systems to improve memory transfer rates. However, the data bus between the GPU and HBM imposes bandwidth limitations due to spatial constraints. Although current buses can reach around 5,000 bits, higher bandwidths are increasingly needed.

Integration of the interposer, GPU, and stacked HBM via a data bus has been employed to enhance AI system performance. Nonetheless, traditional data bus architectures are facing geometric limitations that hinder further improvements.

Consequently, 3D integration of GPUs and HBMs is considered a promising avenue for boosting AI system performance by enabling a higher number of interconnects and reducing signal travel distance.

Despite these advantages, effective thermal management remains an unsolved challenge in 3D-integrated AI systems. Modern high-performance GPUs can consume up to 700 watts, resulting in significant heat generation that is difficult to dissipate.

As the electronics industry—one of the largest global industries—continues to push performance boundaries, IC scaling remains a key metric. However, the IEEE's international Roadmap for Devices and Systems (IRDS) forecasts that post-2027, 3D IC stacking will become the dominant performance driver, with heat dissipation emerging as the primary technical hurdle.

The present disclosure introduces a thermoelectric-cooled interposer as an effective solution for managing heat in 3D IC stacks. This architecture allows for efficient heat extraction from the stacked area, enabling higher data transfer rates and improved thermal performance.

By integrating thermoelectric cooling technology within a 3D stacked configuration, this invention offers substantial improvements in AI computing system performance.

### SUMMARY

One embodiment of the present invention discloses a thermoelectric-cooled interposer system. The thermoelectric cooler comprises a cold region, a hot region, through-cold-region vias (TCVs), a power supply, and a heat exchanger that transports heat out of the 3D stack using a coolant. Both the cold and hot regions feature thin multilayer structures.

In one embodiment, the multilayer structure consists of alternating layers of n-type semiconductor material; metal, and p-type semiconductor material. The TCVs traverse the multilayer cold region. DC circuits are present in both regions, with directional current flow determining temperature distribution. In the cold region, DC current flows from the n-type to the p-type layers; in the hot region, the direction is reversed.

The cold region is designed to be equal to or larger than the die size to ensure effective heat transfer to the hot region. The thermoelectric-cooled interposer facilitates electrical interconnection between electronic components (e.g., GPU and memory chips) on either side via the TCVs.

In another embodiment, the computer system comprises a 3D chip stack formed by a GPU chip, an HBM chip, and the thermoelectric-cooled interposer.

A key feature of the disclosed 3D IC computer system is the separation of the hot and cold regions by the thermoelectric cooler, allowing for efficient thermal management within the 3D IC stack.

### BRIEF DESCRIPTION OF THE DRAWINGS

To facilitate understanding of the invention's features, a more detailed description is provided with reference to illustrative embodiments shown in the accompanying drawings. These drawings are intended to depict typical examples and are not to be considered limiting.

FIG. 1 illustrates an embodiment of a thermoelectric-cooled interposer system.

FIG. 2 shows an embodiment of a 3D IC computer system comprising the thermoelectric-cooled interposer and two stacked chips.

FIG. 3 presents a flow diagram illustrating one embodiment of the manufacturing method for a 3D IC stack that includes the thermoelectric-cooled interposer.

### DETAILED DESCRIPTION

Embodiments of the present invention generally provide an apparatus for a 3D IC computer system. In particular, the embodiments disclosed herein relate to a 3D IC system incorporating a thermoelectric-cooled interposer.

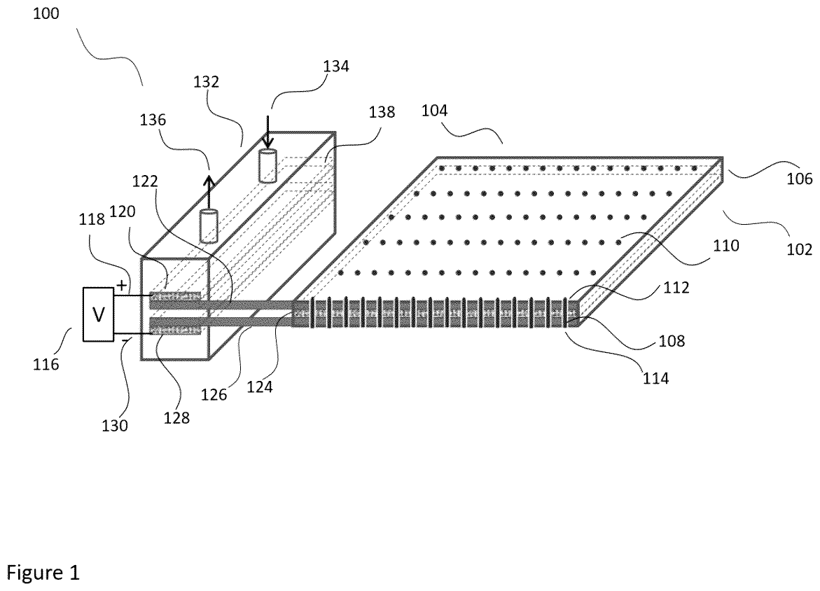

FIG. 1 schematically illustrates a thermoelectric cooling system 100, in accordance with one embodiment of the invention. The system 100 includes a thermoelectric-cooled interposer 102 and a cold region 104.

In one embodiment, the interposer 102 comprises a multilayer 106 fabricated on a silicon wafer using standard semiconductor manufacturing processes such as patterning, implantation, etching, chemical vapor deposition (CVD), physical vapor deposition (PVD), chemical mechanical planarization (CMP), electrochemical deposition (ECD), thinning, and cleaning.

A through-cold-region via (TCV) 108 serves as a conductive interconnection between stacked chips. The TCV 108 has a first end 110 for establishing electrical contact with one of the stacked chips.

The TCV 108 is a columnar conductor surrounded by a dielectric liner 112 for electrical insulation. In one embodiment, the TCV 108 is made of copper and fabricated by depositing copper into a pre-formed via hole using an ECD process.

The TCV 108 also includes a second end 114, electrically connected to the first end 110, enabling vertical interconnection between chips.

A direct current (DC) power supply 116 provides current through a closed loop, including conductive wires 118 and 130, metals 120, 124, and 128, an n-type silicon layer 122, and a p-type silicon layer 126.

The thermoelectric-cooled interposer 102 dissipates heat through a hot region 138, which interfaces with a heat exchanger 132. Coolant enters the exchanger via an inlet 134 and exits through an outlet 136, thereby removing heat from the system.

As DC current flows through the loop, the cold region 104 becomes cooler than the hot region 138. The hot region 138, embedded in the heat exchanger 132, transfers heat to the coolant, which then carries it out of the thermoelectric cooling system 100.

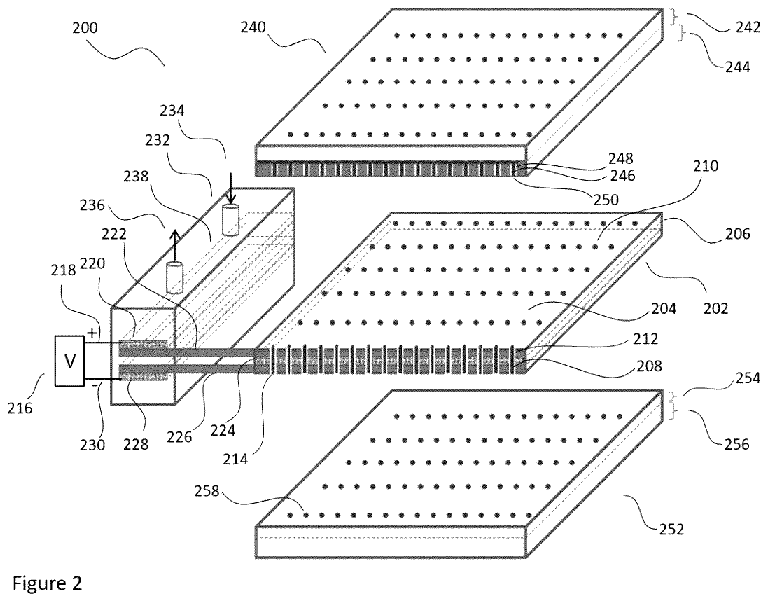

FIG. 2 illustrates a stack system 200 comprising a GPU chip 240, a memory chip 252, and a thermoelectric-cooled interposer 202. The GPU chip 240 includes an integrated circuit (IC) layer 242 and a bulk silicon layer 244. The IC layer 242 houses semiconductor transistors and interconnects for functional operation.

The IC layer 242 is fabricated on a processor wafer using standard semiconductor processing steps such as patterning, implantation, etching, CVD, PVD, CMP, ECD, thinning, and cleaning.

In one embodiment, the IC layer 242 consists of two sub-layers: a device sub-layer with transistors and an interconnect sub-layer. Following formation, the processor wafer is thinned to prepare for stacking.

A through-silicon via (TSV) 246 passes through the bulk silicon layer 244 and is surrounded by a dielectric liner 248 for insulation. A revealed TSV end 250 provides an electrical contact point for stacking.

The TSV end 250 connects to the TCV first end 210 on the thermoelectric-cooled interposer 202. Bonding between the GPU chip 240 and interposer 202 can be performed using traditional or hybrid bonding methods.

A TCV 208 is formed by etching a hole using high-aspect-ratio plasma etching or laser processing, followed by dielectric liner 212 deposition (via PVD or CVD) and copper deposition using ECD.

The thermoelectric-cooled interposer 202 includes a multilayer 206 composed of alternating layers of p-type semiconductor, metal, and n-type semiconductor, deposited using standard PVD or CVD techniques. Both semiconductor types are silicon-based.

On the opposite side of the interposer 202, a second TCV end 214 connects to a contact point 258 on the memory chip 252. In one embodiment, hybrid bonding is used to bond the interposer 202 to the memory chip 252.

The memory chip 252 may be a dynamic random-access memory (DRAM) chip or a high bandwidth memory (HBM) chip. It comprises a device layer 254 and a bulk silicon layer 256. The contact point 258 connects to backend interconnects on the memory chip.

A DC power supply 216 provides current through a loop that includes conductive wires 218 and 230, metals 220, 224, and 228, an n-type silicon layer 222, and a p-type silicon layer 226.

The stack system 200 includes a heat exchanger 232. Coolant flows into the heat exchanger through inlet 234 and exits through outlet 236, expelling heat from the system.

The stack system 200 features a cold region 204 and a hot region 238. As DC current flows, the cold region 204 becomes cooler than the hot region 238. Heat from the GPU chip 240 and memory chip 252 is transferred to the cold region 204 and then to the hot region 238, which dissipates it through the heat exchanger 232.

The GPU chip 240 and memory chip 252 can be stacked onto the thermoelectric-cooled interposer 202 using either traditional thermo-compression bonding or hybrid bonding at near-ambient temperatures.

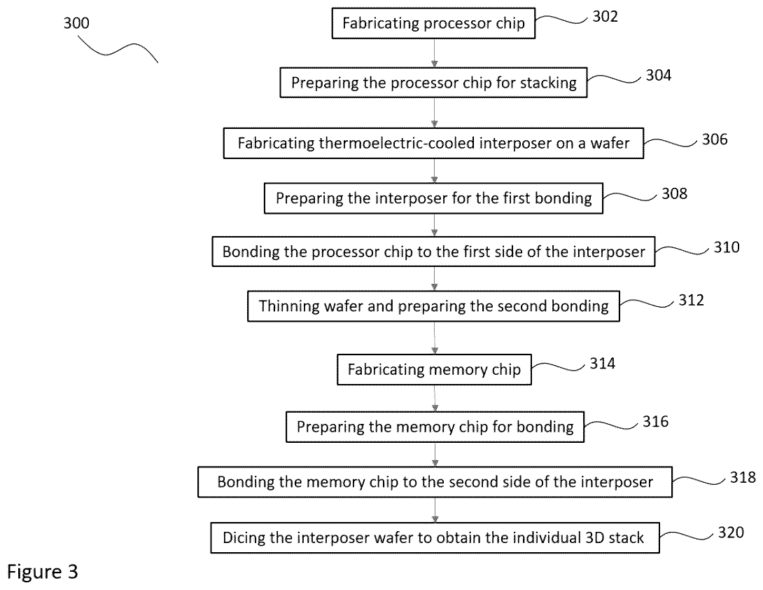

FIG. 3 illustrates a 3D IC stacking flow 300 for manufacturing a 3D IC computer system, in accordance with some embodiments of the present disclosure.

The process begins at block 302, where the processor chip 240 is fabricated on a processor wafer using standard semiconductor processing steps such as lithography, etching, cleaning, PVD, CVD, atomic layer deposition (ALD), ECD, and CMP. The TSV 246 is also formed during this step and electrically connected to the chip circuitry.

At block 304, the bulk silicon layer 244 is thinned via grinding and planarized via CMP, exposing the TSV end 250. The wafer is then singulated into individual processor chips 240.

At block 306, the thermoelectric-cooled interposer 202 is fabricated on an interposer wafer. The interposer includes a thermoelectric cooler composed of alternating materials (e.g., n-type and p-type semiconductors). When DC current flows through these materials, temperature differences arise due to differing work functions, causing one junction to heat and the opposite junction to cool. In one embodiment, a thin metal layer is placed between semiconductor layers to prevent interdiffusion. The cold and hot regions are formed from multilayer structures. TCVs are then fabricated by etching holes, depositing a dielectric liner, and filling with copper.

At block 308, a CMP process planarizes the interposer surface and reveals the first end 210 of the TCVs in preparation for stacking.

At block 310, the TCV first end 210 is bonded to the TSV end 250 of the processor chip 240. In one embodiment, hybrid bonding is employed, joining both dielectric and conductive areas.

At block 312, the interposer wafer is thinned and planarized using CMP to prepare for bonding with the memory chip 252. The second end 214 of the TCVs is revealed during this step.

At block 314, the memory chip 252 is fabricated. This may involve standard DRAM fabrication or the stacking of dies to form an HBM.

At block 316, grinding and CMP processes are used to expose the connection point 258 on the memory chip 252. Plasma treatment may be used to prepare the bonding surface.

At block 318, the connection point 258 is bonded to the second end 214 of the TCVs on the interposer 202.

At block 320, the assembled wafer is singulated into individual dies using dicing methods such as sawing, laser cutting, plasma cutting, or hybrid dicing. Following singulation, the dies are packaged for final use and shipment to end users.

What is claimed is:

1. A self-cooled interposer configured to connect a first electronic component to a second electronic component, comprising:
A thermoelectric cooler comprising a cold region and a hot region, wherein the cold region is configured to dissipate heat generated by the first electronic component and/or the second electronic component; and
A plurality of through-cold-region vias (TCVs), wherein a plurality of first ends of the TCVs are connected to the first electronic component and a plurality of second ends of the TCVs are connected to the second electronic component.

2. The self-cooled interposer of claim 1, wherein the cold region comprises alternating layers of an n-type semiconductor, a metal layer, and a p-type semiconductor.

3. The self-cooled interposer of claim 1, wherein the hot region comprises alternating layers of a p-type semiconductor, a metal layer, and an n-type semiconductor.

4. The self-cooled interposer of claim 1, wherein the first electronic component is a graphics processing unit (GPU).

5. The self-cooled interposer of claim 1, wherein the first electronic component is a central processing unit (CPU).

6. The self-cooled interposer of claim 1, wherein the second electronic component is a memory chip.

7. The self-cooled interposer of claim 1, wherein the second electronic component is an interposer.

8. The self-cooled interposer of claim 1, wherein heat generated by the hot region is removed from the interposer via a flowing liquid coolant.

9. The self-cooled interposer of claim 1, wherein the first electronic component is bonded to the first ends of the TCVs.

10. The self-cooled interposer of claim 1, wherein the second electronic component is bonded to the second ends of the TCVs.

11. A method of stacking integrated circuit (IC) chips, comprising:
a. Fabricating a first chip comprising conductive vias for interconnection;
b. Fabricating a self-cooled interposer on a wafer, the interposer comprising alternating layers of an n-type semiconductor, a metal layer, and a p-type semiconductor, and including a cold region and a hot region;
c. Forming a plurality of through-cold-region vias (TCVs) in the interposer and exposing first ends of the TCVs, wherein the TCV pattern aligns with the conductive vias of the first chip;
d. Aligning the first chip and the interposer, and bonding the conductive vias of the first chip to the first ends of the TCVs;
e. Thinning the wafer and exposing second ends of the TCVs;
f. Fabricating a second chip comprising interconnect metal vias;
g. Aligning the second chip and the interposer, and bonding the interconnect metal vias of the second chip to the second ends of the TCVs to form a stacked structure; and
h. Singulating the stacked chips.

12. The method of claim 11, wherein the bonding in steps (d) and (g) is hybrid bonding.

13. The method of claim 11, wherein the first chip is a graphics processing unit (GPU).

14. The method of claim 11, wherein the second chip is a memory chip.

15. The method of claim 11, wherein the TCVs include dielectric liners.
